(19) United States
(12) Patent Application Publication
(10) Pub. No.: US 2011/0284990 A1
(43) Pub. Date: Nov. 24, 2011

(54) Process for making an alignment structure in the fabrication of a semiconductor device

(75) Inventors: Anbu Selvam Mahalingam, Kulim Pedana (MY); Venkatesh Madhaven, Penang (MY)

(73) Assignee: SILTERRA MALAYSIA SDN BHD, Kedah (MY)

(21) Appl. No.: 13/097,970

(22) Filed: Apr. 29, 2011

(30) Foreign Application Priority Data
Apr. 30, 2010 (MY) PI2010001986

(51) Int. Cl. H01L 21/28; H01L 29/92; B82Y 40/00

(52) U.S. Cl. 257/532; 438/381; 977/888; 257/E21.158; 257/E29.343

(57) ABSTRACT

A process for making an alignment structure in manufacturing a semiconductor device, comprising copper interconnect (Cu-interconnect) fabrication involving chemical-mechanical planarization (CMP) is disclosed. The process comprises tailoring said CMP process to produce a sufficiently high dishing on a designated alignment key area during bulk removal of Cu. The additional dishing step would have sufficient step height for optical pickup to produce alignment signal. Subsequent photolithographic processes specifically for making conventional alignment structure may thus be omitted. Preferably, the additional dishing is achieved by control over any one or combination of pressuring, vacuuming and/or venting of a CMP head's membrane, inner tube and retaining ring chambers, and selection of any one or combination of pads, slurry, pad conditioner and recipe, and may only need to achieve a removal of up to 100 \dot{A}. Our process may be adapted for fabricating a MIM top and MIM bottom layers via 2 masking processes, wherein the additional dishing is created as a narrow metal line. It may also be adapted for fabricating an MIM capacitor wherein the underlying Cu layer is used as the bottom plate of the MIM. The additional dishing does not appear to affect electrical properties of the underlying Cu layer.

### TECHNICAL FIELD

This invention relates to a process for making an alignment structure in semiconductor fabrication. In particular, it relates to a chemical-mechanical planarization (CMP) process in copper interconnect (Cu-interconnect) fabrication, such as that in metal-insulator-metal (MIM) capacitors.

### BACKGROUND OF THE INVENTION

In the fabrication of semiconductor devices involving copper interconnects (Cu-interconnect), it is often necessary to align one layer of mask set or patterning to an underlying layer. The alignment process requires aligning a top metal plate to a bottom metal plate or to an underlying layer to achieve proper connectivity. Such alignment poses unique challenges such as in the fabrication of a metal-insulator-metal (MIM) capacitor.

Taking the MIM capacitor as an example, a conventional process requires 3 mask sets whereby each is designed to pattern (i) a bottom metal plate, (ii) a top metal mask, and (iii) an alignment mark as a key to aligning the bottom metal and top metal mask to the previous or underlying Cu-interconnect. The 3^{rd} mask is required because metal stacks are opaque to optical light thus causing poor alignment signals with existing scanners when aligning to the preceding Cu underlying layer. This 3^{rd} mask set has no other use anywhere else in the die and is solely for the purpose of creating an alignment structure, which is usually in a trench formed upon via patterning, etching and cleaning after the underlying metal layer is completed. Subsequent metal stacks are then deposited, patterned and cleaned to complete the Cu-interconnect.

An example of a conventional process flow for MIM capacitor is shown in FIG. 1A (Prior Art) to 1F (Prior Art). Briefly, post-Cu-CMP and dielectric stop etch and barrier layer deposition (FIG. 1A) is followed by post-alignment masking and etching (FIG. 1B) and post-MIM metal and dielectric stack deposition (FIG. 1C). Next, post-MIM top plate masking and etching steps (FIG. 1D) are carried out, followed by post-MIM bottom plate masking and etching (FIG. 1E) and lastly a post-top via and top-metal fabrication step (FIG. 1F).

Much of the prior art methods involve preserving alignment marks during fabrication such as that disclosed in U.S. Pat. No. 6,750,115 (Infineon) in respect of MIM capacitor fabrication and WO 2003/003457 (Infineon) in respect of MRAM, or that disclosed in U.S. Pat. No. 6,933,191 (IBM), which proposed to use semi-transparent metallic electrode layer made from indium-tin-oxide (ITO) as the bottom plate instead of titanium oxide in conventional MIM so as not to obliterate the alignment trench in the lower layer, thus being able to do with one less mask.

US-2009/61590 (Hwang) discloses another example of a method for retaining earlier formed trenches for alignment use so that alignment key-forming process steps may be reduced. Yet another type of features formed for alignment purposes may be in the form of a step such as that disclosed in U.S. Pat. No. 7,399,700 (Samsung Electronics) which may comprise of a dummy interconnection in a stepped region of the alignment key. In U.S. Pat. No. 7,436,016 (Infineon) it is disclosed how the need for alignment of an MIM capacitor's top plate may be done away with. Because the top late is formed in a damascene process, after a CMP step, a mask and etch process is not required to form the top plate, which solves alignment problems for the top plate.

Cu-CMP dishing. Copper CMP process is a conventional process for bulk removal of Cu layer and typically may be broken down into three (3) process steps. The 1^{st} step is the bulk copper removal step, followed by a soft-landing, low pressure polishing step. The 2^{nd} step concerns clearing all remaining copper. Step 3 is an over-polish step where the topography induced in the preceding two steps is reduced and a final oxide thickness is targeted. A Cu-CMP process typically endeavours to reduce or minimise dishing. As such, any alignment feature must be protected therefrom; otherwise it would result in significant reduction or loss of step height that would be necessary to provide a strong signal for photolithography. Examples of slurry compositions that might be used in a CMP process may be found in U.S. Pat. No. 7,229,570 (NEC).

Sometimes, however, dishing may be deliberately created such as that disclosed in U.S. Pat. No. 7,120,988 (Hitachi) where it is specifically created on the top of the write pole of a magnetic write head rather than in a semiconductor device embodied in an integrated circuit. In KR-20010046915 (Hynix) and KR-20050002493 (Hynix) underlying structures are relied upon for creating dishing effect. In these two Korean patents, a trench and/or align key pattern formed are further coated by an oxide layer using for example thermal oxidation. A high-density plasma (HDP) oxide layer is then used to fill the trench. CMP is performed on the resultant structure and dishing is created on the HDP oxide layer. The dishing resulted in a stepped portion which is used as an alignment key.

### SUMMARY OF THE INVENTION

It is desirous in the fabrication of Cu-interconnect, where alignment marking is required, that the conventional CMP process be customizable to create an alignment mark for subsequent photolithographic processes. The alignment mark is created so that a mask set specific for creating the alignment structure is not needed, thus saving resources and time. It is also desirous for such process to create the alignment mark without affecting the underlying metal's electrical properties.

For specific applications such as fabrication of MIM capacitors, our present invention also endeavours to create the alignment by optimizing or tailoring the Cu-CMP process for the metal layer below the MIM capacitor. Our process also strive to cater for variations in the device's fabrication such as whether a separate bottom plate isolated from Cu metallization or the conventional Cu metallization itself is taken as the bottom plate. It is further desirous that the resultant dishing effect to be used as alignment mark has stepping of sufficient height to enable detection or allow a signal that is strong enough, e.g. for optical pickup.

The general embodiment of our process for making an alignment structure in manufacturing a semiconductor device, comprising copper interconnect (Cu-interconnect) fabrication involving chemical-mechanical planarization (CMP) process (Cu-CMP), the process comprising the steps of:

(i) tailoring said Cu-CMP process to produce a sufficiently high dishing on a designated alignment key area during bulk removal of Cu; and
(ii) allowing subsequent photolithographic processes to optically detect said dishing as said alignment structure
for aligning a top layer to an underlying layer, including aligning a top metal plate to a bottom metal plate in Cu-interconnect fabrication.

Preferably, the tailored CMP process comprises allowing for at least an additional dishing step on the designated alignment key area to a sufficient height for optical pickup. Our process may be advantageous used where the Cu-interconnect fabrication comprises a dual damascene process or for manufacturing a metal-insulator-metal (MIM) capacitor, including Cu-CMP processes that uses multi-platen, or including electrochemical mechanical planarization (e-CMP).

Advantageously, our process enables subsequent photolithographic processes to omit those process steps specifically for making conventional alignment structure. Preferably, the additional dishing is achieved by control over any one or combination of pressuring, vacuuming and/or venting of a CMP head's membrane, inner tube and retaining ring chambers, and selection of any one or combination of pads, slurry, pad conditioner and recipe, and may only need to achieve a removal of up to 100 \dot{A} of Cu from the Cu layer.

In one aspect, our process may be adapted for fabricating a MIM top and MIM bottom layers via 2 masking processes, wherein the additional dishing is created as a narrow metal line. The additional dishing substantially maintains the relevant electrical properties of the underlying Cu layer.

In another aspect, our process may also be adapted for fabricating an MIM capacitor wherein its bottom plate is fabricated from the underlying Cu layer in which a masking step may be omitted and the bottom plate may be provided with sheet resistance lower than conventional resistance wherein the dishing aligns the top plate to the bottom plate.

### BRIEF DESCRIPTION OF THE DRAWINGS

The drawings accompanying this specification as listed below may provide a better understanding of our invention and its advantages when referred in conjunction with the detailed description the follows as exemplary and non-limiting embodiments of our method, in which:

FIG. 1 (Prior Art) which is comprised of FIG. 1A to FIG. 1F, shows the conventional Cu-CMP process in the fabrication of an MIM capacitor.

FIGS. 2 to 6 illustrate one embodiment of our process steps for post-Cu-CMP.

FIG. 7 embodies a graph comparing alignment signal strength quality based on WQ (Wafer Quality).

FIG. 8 exemplifies graphs comprising tests in which electrical performance is compared between standard MIM capacitors and ours.

FIGS. 9 and 10 are SEM images showing the lack of adverse impact of dishing;

FIG. 11 is another SEM image illustrating lack of dishing impact for another wide structure, and

FIG. 12 is a graph exemplifying the WQ characterization of the Cu bottom plate that has undergone the additional Cu-CMP polishing according to our invention.

FIGS. 13A and 13B are graphs illustrating the I-V curves compared between the standard MIM capacitor and that of our process.

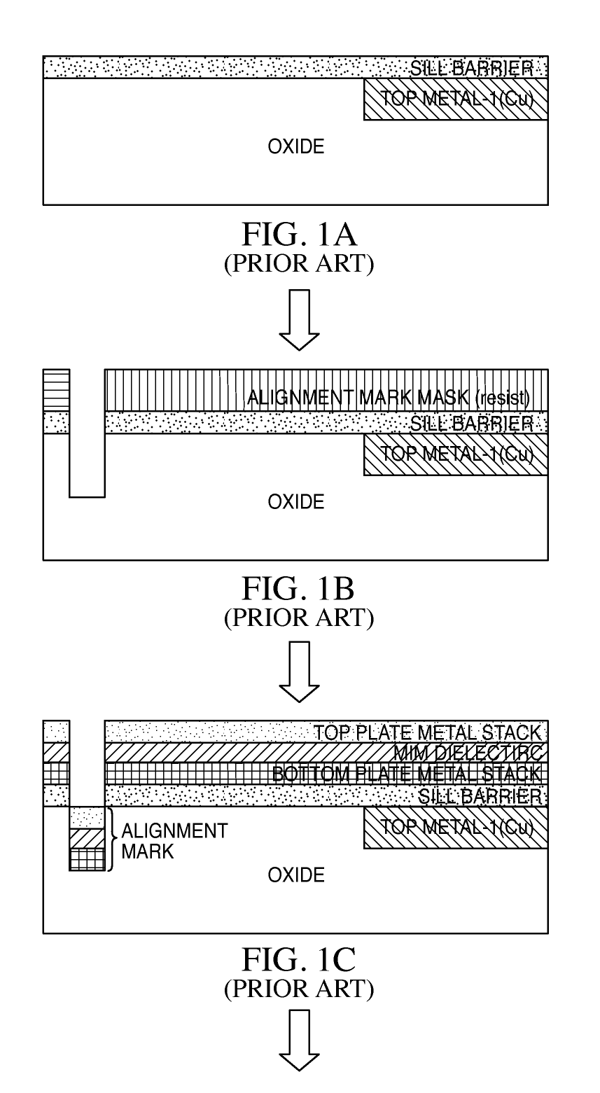

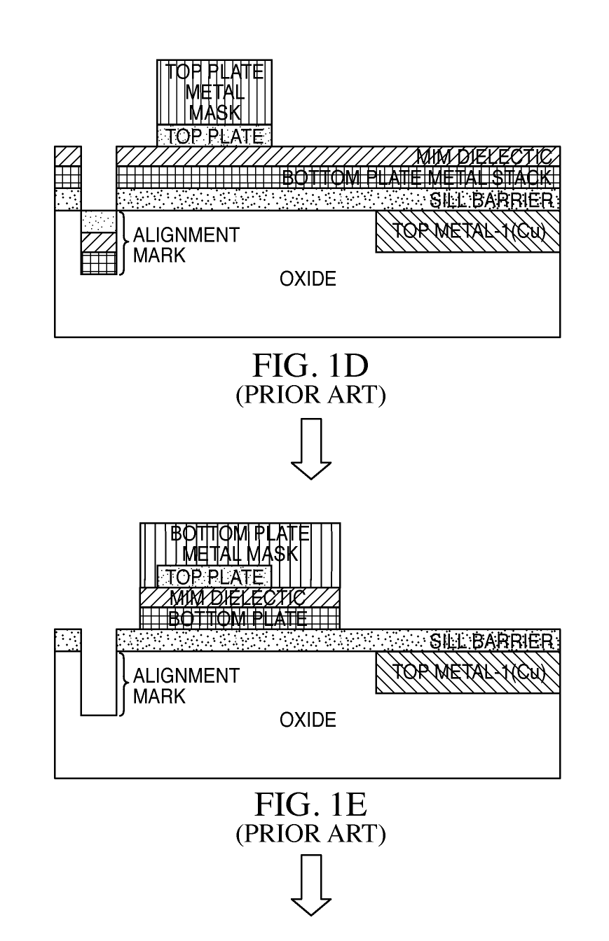

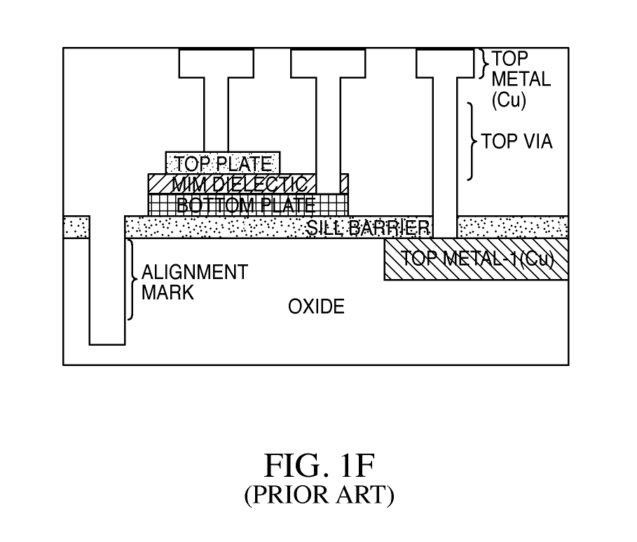

### DETAILED DESCRIPTION OF EMBODIMENTS

As mentioned previously, a Cu-CMP process comprises three (3) process steps, (or stages), i.e. (i) bulk copper removal, which is followed by a soft-landing low pressure polishing step; (ii) clearing all remaining copper and (iii) over-polishing step where the topography induced in the 2 preceding steps is reduced and a final oxide thickness targeted. After a typical Cu-CMP process, dishing within the copper line is minimized. The low dishing is the reason why any feature to be used for an alignment mark would have insufficient step height to provide a strong signal for subsequent photolithography.

Briefly, our present process is for making an alignment structure in the manufacturing of a semiconductor device comprising Cu-interconnect fabrication, including CMP process which is may be customized to produce a sufficiently high dishing on a designated alignment key area during bulk removal of copper. Subsequent photolithographic processes may then use the dishing for alignment purposes.

It should be noted that customizing or tailoring the CMP process here may mean either positive or negative aspects of planarization. By “positive”, we mean actively or deliberately creating an additional step or process so that the high dishing effect is achieved. By “negative” we mean passive or deliberately allowing a conventional CMP process to be less effective or decreasing the planarization target so that dishing is not normally reduced and thus result in high dishing.

The following description will first illustrate the positive aspect of the customized CMP wherein an additional step is performed to create the dishing having a step sufficiently high for alignment signalling purposes such as a step or height that may be picked up by conventional optical sensor, e.g. a photo diode disclosed in US-2009/0130793 (Samsung Electronics) employed in CD and DVD readers. Our inventive process is applicable for making an alignment structure in Cu-interconnect fabrication processes, such as that involving dual damascene process, for manufacturing MIM capacitors or where multi-platen approach is involved.

In all such processes, as subsequent photolithography are able to use the high dishing as an alignment mark since its height is sufficient, subsequent process steps that are solely for making conventional alignment mark may now be omitted, thus saving resources and time.

The high dishing step may be achieved by adding an additional step to the conventional Cu-CMP process wherein the additional step adds dishing to a sufficient height to achieve a feature having a size about that of the intended alignment mark through careful process control on various parameters including control over the pressure, vacuum and/or venting of a CMP head's membrane, inner tube and retaining ring chambers and (ii) a selection of any one or combination of pads, slurry and pad conditioner, as well as the recipe.

One process which we had successfully used to achieve the high dishing effect include the following parameters:
PV in the range of 140-180 psi/rpm;
Pads: hard pad, IC-based pad;
Slurry: alumina-based slurry; 75-100 ml/min;
Pad conditioner: 6 psi, diamond-coated;
Removal amount: not measureable but estimated to be <100 \dot{A}over the alignment feature with short polish time at post-planarization.

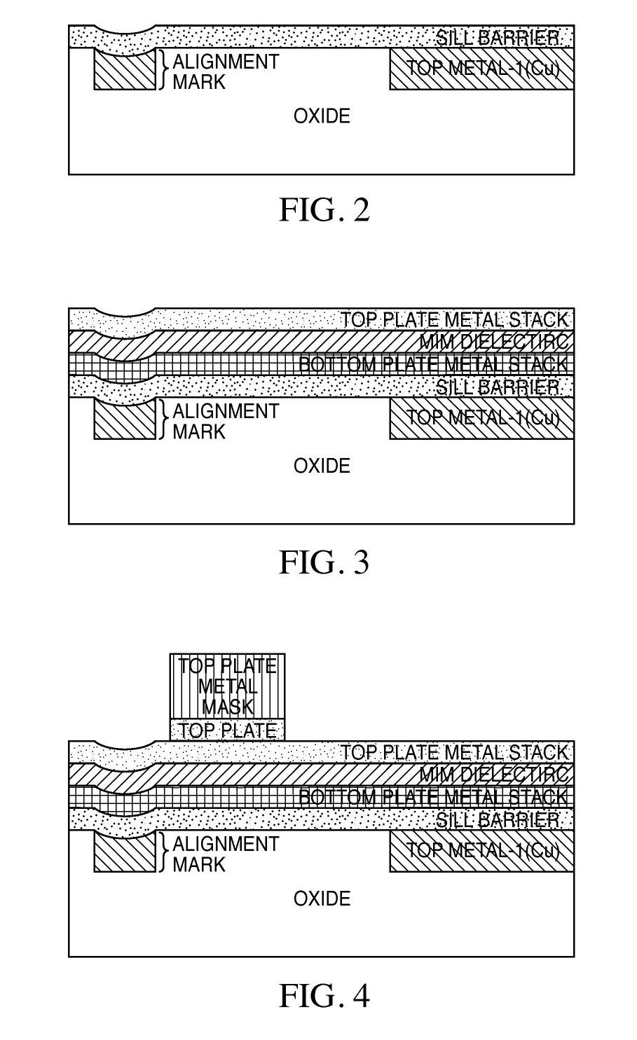

With collective reference to FIGS. 2-6, a typical post-Cu-CMP process may be shown in the first embodiment of our process which involves fabricating a MIM top and MIM bottom layers, i.e. involving 2 masking processes. In this specific embodiment, a modified high dishing step may be employed during bulk polishing of the Cu layer in Platen 1 after completing the standard 3-step copper CMP process. This step is customized to increase the dishing in the alignment mark thus improving the alignment signal for a scanner to locate the mark in order to successfully align the MIM top plate and bottom plate masks to the previous or underlying Cu layer.

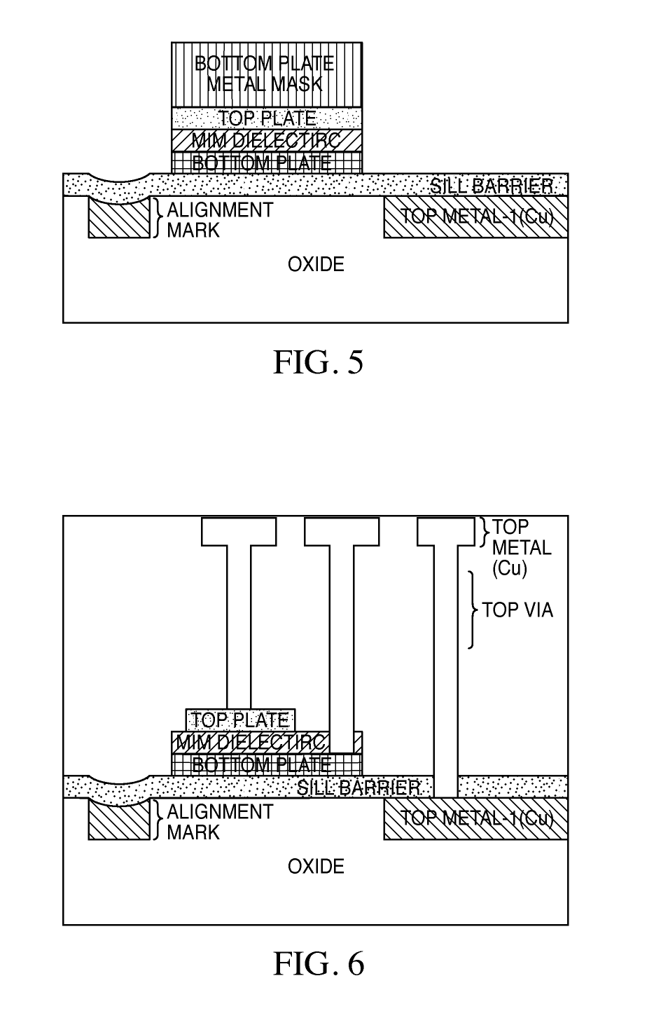

Post Cu-CMP and stop etch layer deposition are shown in FIG. 2 wherein the high dishing area is shown marked in a circle. The highly dished area is preferably created in a narrower metal line. Dishing at a wider metal line during this process does not appear to have significantly affected any electrical performance of the device. Subsequent photolithographic processes are shown in later drawings where in FIG. 3 is shown the post-MIM metal and dielectric stack deposition steps while FIG. 4 illustrates post-MIM top plate mask & etch. FIG. 5 shows the post-MIM bottom plate masking and etching while FIG. 6 illustrates the post-top via and top metal forming process.

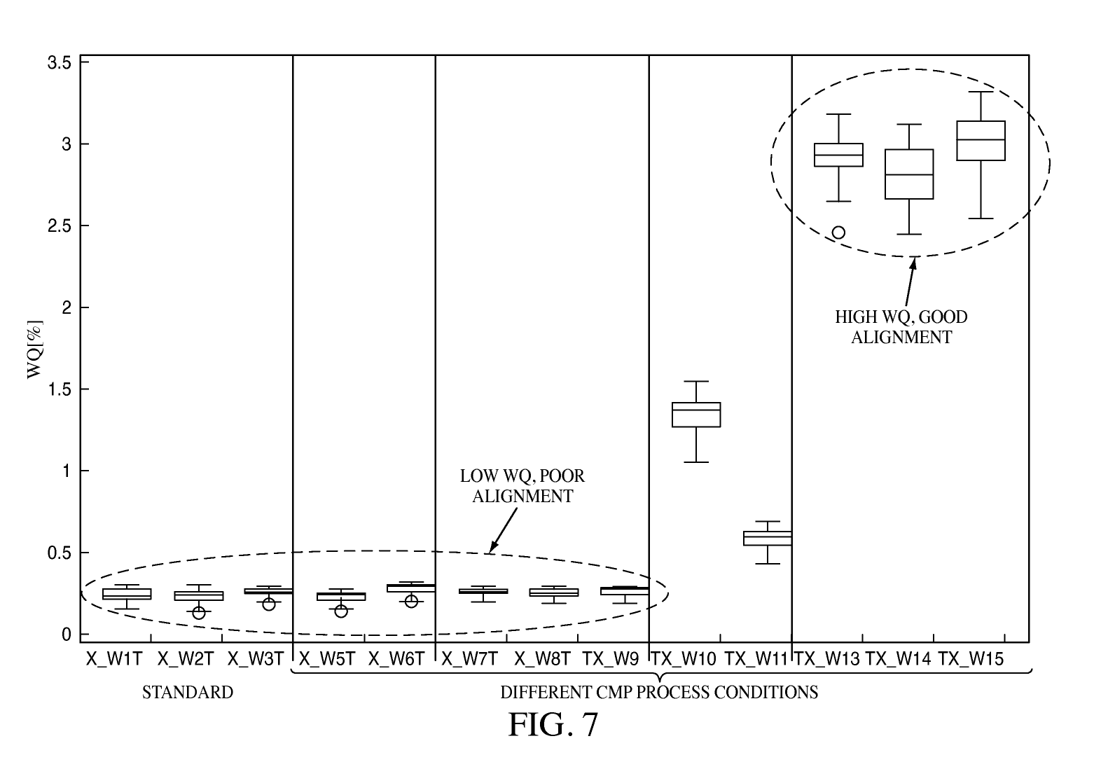

Our proposed method of using Cu-CMP with effectively high dishing as the alignment mark does not appear to affect the prime die, which electrical performance has been tested and characterized with various widths on the metal layer. The results of these tests indicate that our novel Cu-CMP process has no effect on sheet resistance of the metal in the prime die. A comparison of alignment signal strength quality shown in FIG. 7 based on WQ (“Wafer Quality”, which is a term for the percentage of actual signal strength with reference to signal generated by fiducial mark) wherein the MIM alignment quality is compared between a standard and one that is produced with our process.

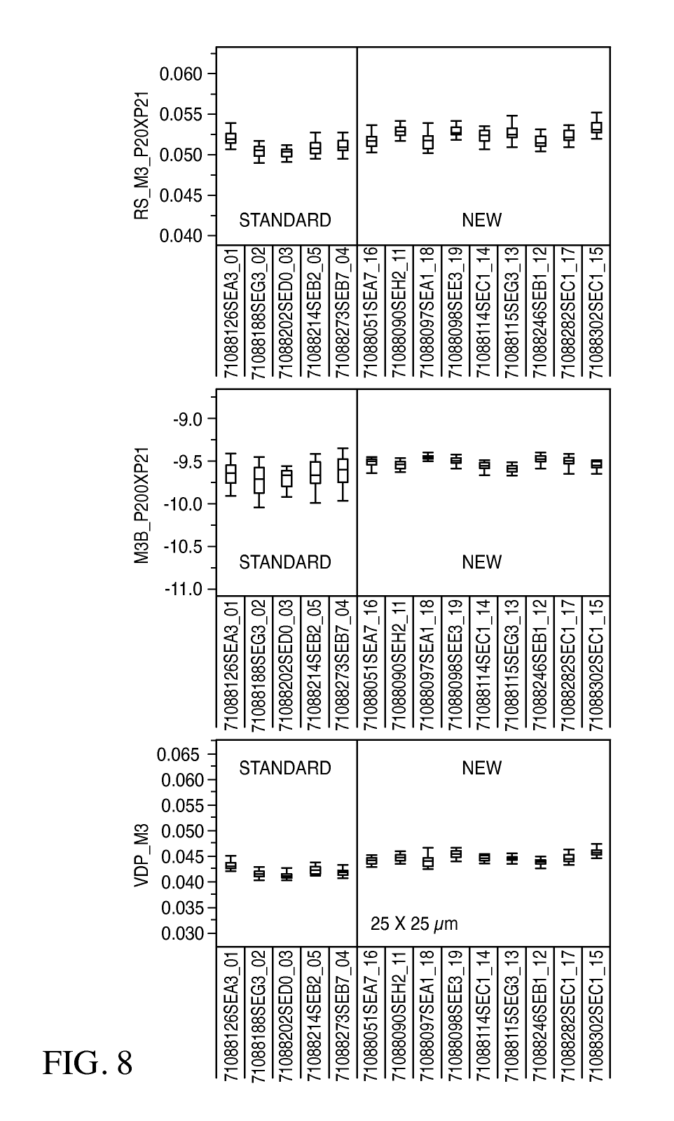

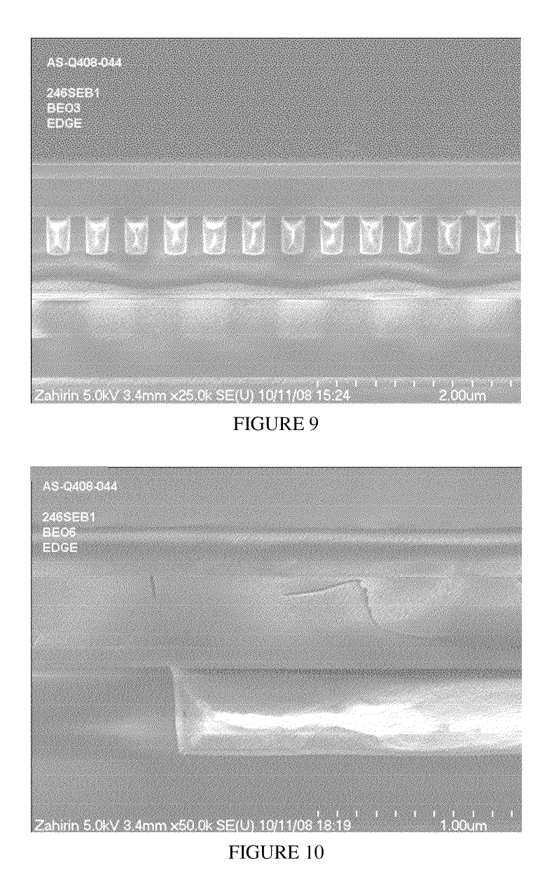

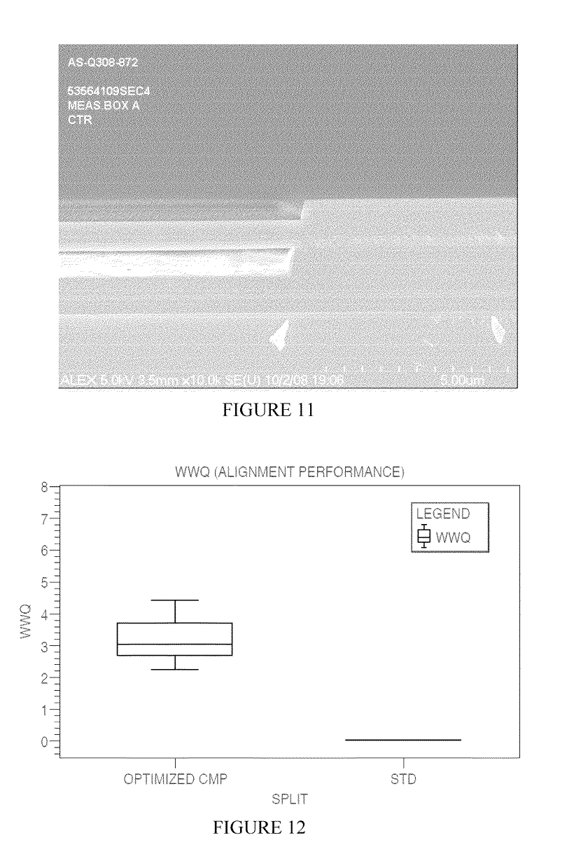

FIG. 8 shows test results of electrical performance comparison between the conventional (“Std”) and one that is produced with our process, wherein the results show that our additional dishing does not affect the relevant electrical parameters of the underlying Cu layer (below MIM). Physical examination of the high dishing feature by SEM imaging as shown in FIG. 9 and FIG. 10 does not show any significant erosion or adverse dishing impact on the underlying metal in narrow and wide structures. For wide structures, such as 80 gm wide examined under SEM imaging shown in FIG. 11, no significant dishing impact has been detected.

In a second embodiment, our process may be employed in the fabrication of an MIM capacitor where the underlying Cu layer is used as the MIM bottom plate. In this embodiment, the masking step for the bottom plate may thus be omitted, resulting in only 1 masking step being required, i.e. that for the MIM top plate. As a result, a lower sheet resistance may be provided for the MIM bottom plate and may thus be advantageous for higher frequency application or increased throughput.

This second embodiment also produces a high dishing which is used for aligning the MIM top plate to the bottom plate, i.e. to the Cu layer. The increase in the dishing in the alignment mark may thus improve the alignment signal for the scanner to successfully align the MIM top plate to the Cu-layer as the bottom plate. The rest of the process for this second embodiment is the same as in the first, i.e. utilizing a modified or customized high dishing step during bulk polishing of Cu (Platen 1) after completed the standard 3-step Cu-CMP process.

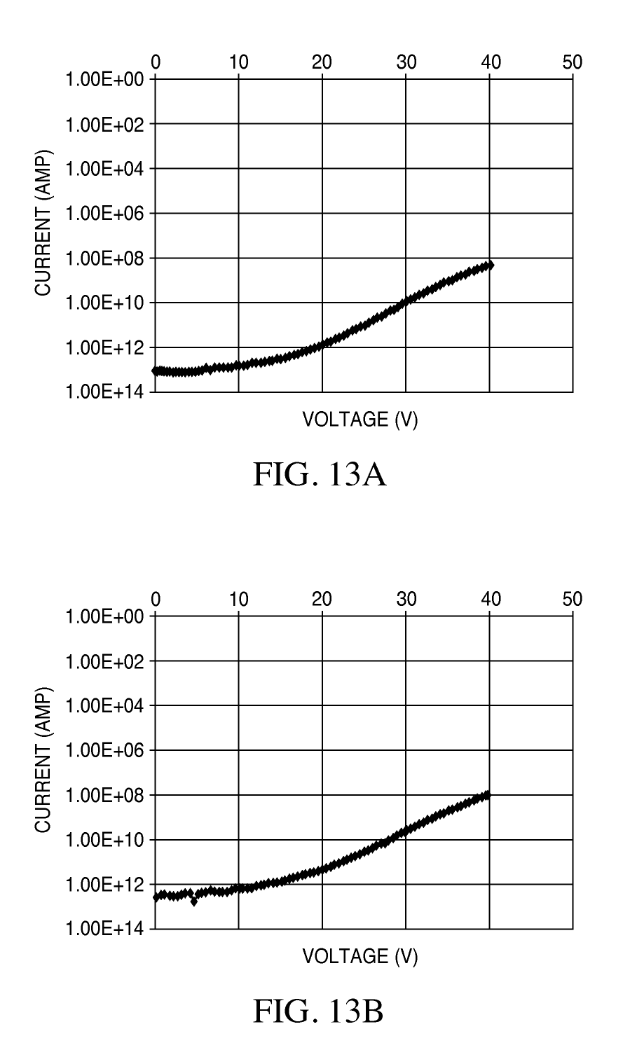

This approach has also been validated by tests and characterization of WQ (wafer alignment quality) wherein excellent improvement of wafer alignment at the top plate masking step, as shown in FIG. 12 with respect to the additional CMP polishing of the Cu bottom plate. Moreover, measuring the current-voltage (I-V) curve of the MIM capacitors with Cu as the bottom plate, as shown in FIG. 13A (which shows the I-V curve of an MIM capacitor with additional bottom plate CMP polishing) and FIG. 13B (which shows the I-V curve of an MIM capacitor with standard bottom plate CMP polishing) may also demonstrate the successful integration of MIM structures with Cu-layer as the bottom plate. As these graphs show, the additional CMP process, which results in improved alignment, does not negatively affect the MIM capacitor's characteristics.

The tailoring of the Cu-CMP process in accordance with the invention produces a sufficiently high dishing effect on a designated alignment key area during bulk removal of Cu. Such a tailored Cu-CMP process may include at least an additional dishing step on the designated alignment key area to attain the sufficient height to achieve a feature having a size about that of the intended alignment mark. The attained height is step height or dishing depth, rather than being the height from which an optical sensor should be placed above the die surface to detect the depression.

Apart from the afore-described embodiments of our method for providing an alignment mark via high dishing with a post Cu-CMP process, it would be obvious to a skilled person that many aspects or consequential advantages of our invention may be presented in other variations, substitution or modifications thereof without departing from the essence and working principles of the invention. For example, there is the advantage of traceability of our process which may be traced from the details of the Cu-CMP process recipe. Another example might be where the CMP process might be adapted to include electrochemical mechanical planarization (e-CMP) to achieve the similar high dishing effect. Such variations or modifications are to be considered as falling within the letter and scope of the following claims.

1. A process for making an alignment structure in manufacturing a semiconductor device comprising copper interconnect (Cu-interconnect) fabrication involving chemical-mechanical planarization (CMP) process (Cu-CMP), the process comprising the steps of:
(i) tailoring said Cu-CMP process to produce a sufficiently high dishing on a designated alignment key area during bulk removal of Cu;
(ii) allowing subsequent photolithographic processes to optically detect said dishing as said alignment structure for aligning a top layer to an underlying layer, including aligning a top metal plate to a bottom metal plate in Cu-interconnect fabrication.

2. A process for making an alignment structure according to claim 1 wherein the tailored Cu-CMP process comprises allowing for at least an additional dishing step on the designated alignment key area to a sufficient height.

3. A process for making an alignment structure according to claim 1 wherein the Cu-interconnect fabrication comprises a dual damascene process.

4. A process for making an alignment structure according to claim 3 wherein the Cu-interconnect fabrication comprises the manufacture of at least a metal-insulator-metal (MIM) capacitor.

5. A process for making an alignment structure according to claim 1 wherein the subsequent photolithographic processes allows masking steps specifically for making conventional alignment structure to be omitted.

6. A process for making an alignment structure according to claim 1 wherein the Cu-CMP process uses a multiplaten approach.

7. A process for making an alignment structure according to claim 1 wherein the Cu-CMP process includes electrochemical mechanical planarization (e-CMP).

8. A process for making an alignment structure according to claim 2 wherein the additional dishing is achieved by control over any one or combination of pressuring, vacuuming and/or venting of a CMP head's membrane, inner tube and retaining ring chambers, and selection of any one or combination of pads, slurry, pad conditioner and recipe.

9. A process for making an alignment structure according to claim 2 wherein the additional dishing results in a removal of up to 100 \dot{A} of Cu from the Cu layer.

10. A process for making an alignment structure according to claim 4 for fabricating a MIM top and MIM bottom layers via 2 masking processes.

11. A process for making an alignment structure according to claim 2 wherein the additional dishing is created as a narrow metal line.

12. A process for making an alignment structure according to claim 2 wherein the additional dishing substantially maintains the relevant electrical properties of the underlying Cu layer.

13. A process for making an alignment structure according to claim 4 wherein the MIM capacitor has a bottom plate fabricated from an underlying Cu layer.

14. A process for making an alignment structure according to claim 13 wherein a masking step is omitted.

15. A process for making an alignment structure according to claim 13 wherein the bottom plate is provided with sheet resistance lower than conventional resistance.

16. A process for making an alignment structure according to claim 13 wherein the dishing aligns the top plate to the bottom plate of the MIM capacitor.

17. A semiconductor device comprising microelectronic component including a Cu-interconnect fabricated according to a process according to claim 1.

18. A semiconductor device according to claim 17 wherein the microelectronic component includes a capacitor.

19. A semiconductor device according to claim 18 wherein the capacitor is a metal-insulator-metal (MIM) capacitor.

20. A semiconductor device according to claim 17 comprised in a complementary metal oxide semiconductor (CMOS) device or manufactured in a CMOS fabrication technology.
